(19) United States
(12) Patent Application Publication
(10) Pub. No.: US 2014/0362554 A1
(43) Pub. Date: Dec. 11, 2014

(54) Display Device

(71) Applicants: Kabushiki Kaisha Toshiba, Tokyo (JP); Toshiba Lifestyle Products & Services Corporation, Tokyo (JP)

(72) Inventor: Kazuyuki Rikiishi, Ome-shi (JP)

(21) Appl. No.: 14/466,847

(22) Filed: Aug. 22, 2014

Related U.S. Application Data
(63) Continuation of application No. PCT/JP2013/059701, filed on Mar. 29, 2013.

(51) Int. Cl. H05K 5/00; H05K 5/02

(52) U.S. Cl. CPC H05K 5/0004; H05K 5/0017; H05K 5/0243
USPC 361/809

(57) ABSTRACT

According to one embodiment, a display device includes a display unit, a second member, and a third member. The display unit includes a display panel and a first member. The display panel includes a first face on which an image is displayed. The first member includes a first wall covering a periphery of the first face and defining an opening configured to expose the first face. The second member is configured to cover a second face of the display unit opposite the first face. A gap is provided between the second wall and the second face. The third member includes a third wall, a support, and a fourth wall. The third wall is configured to cross the first face and the second face, is configured to cover a third face of the display unit extended between the first face and the second face, and has a thickness thicker than thicknesses of the first wall and the second wall. The support is configured to support the second member at a position separated from the second face of the display unit toward a side opposite the first face. The fourth wall is extended between the third wall and the support.

### CROSS-REFERENCE TO RELATED APPLICATIONS

This application is a continuation of international application No. PCT/JP2013/059701, filed Mar. 29, 2013, which designates the United States, incorporated herein by reference.

### FIELD

Embodiments described herein relate generally to a display device.

### BACKGROUND

Conventionally, there is known a display device in which a frame-like part of a casing covers a periphery of a display panel.

In a display device of such a type, it is desirable to efficiently obtain a member constituting the casing.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of one example of a display device according to an embodiment;

FIG. 2 is an exemplary side view of one example of the display device in the embodiment;

FIG. 3 is an exemplary exploded perspective view of one example of a display unit included in the display device in the embodiment;

FIG. 4 is an exemplary cross-sectional view taken along a line IV-IV of FIG. 1, in the embodiment;

FIG. 5 is an exemplary plan view of one example of a layout of when first and second members included in the display device are cut out from one plate material, in the embodiment; and

FIG. 6 is an exemplary cross-sectional view equivalent to the cross-sectional view of FIG. 4 and illustrating an example of a display device according to a first modification.

### DETAILED DESCRIPTION

According to one embodiment, a display device comprises a display unit, a second member, and a third member. The display unit comprises a display panel and a first member. The display panel comprises a first face on which an image is displayed, The first member comprises a first wall covering a periphery of the first face and defining an opening configured to expose the first face. The second member is configured to cover a second face of the display unit opposite the first face. A gap is provided between the second wall and the second face. The third member comprises a third wall, a support, and a fourth wall. The third wall is configured to cross the first face and the second face, is configured to cover a third face of the display unit extended between the first face and the second face, and has a thickness thicker than thicknesses of the first wall and the second wall. The support is configured to support the second member at a position separated from the second face of the display unit toward a side opposite the first face. The fourth wall is extended between the third wall and the support.

An embodiment and a modification described hereinafter have similar configurations. In the following, the same reference numerals are given to the same components, and the description thereof will be omitted. In each figure, directions are illustrated for convenience of description. The X-direction is a longitudinal direction of a display device (casing), the Y-direction is a short length direction of the display device, and the Z-direction is a thickness direction of the display device. The X-, Y-, and Z-directions cross one another (at right angles). In the present embodiment, the X-direction is an example of a second direction, and Y-direction is an example of a first direction.

### Embodiment

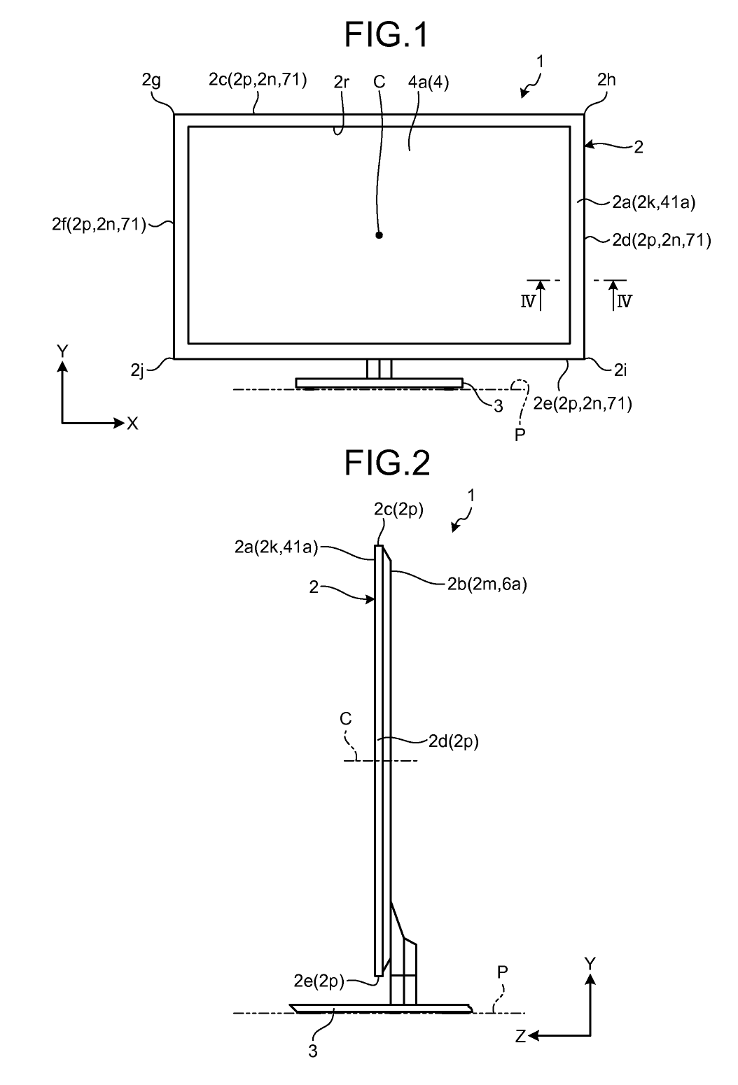

A display device 1 (video display device, image display device, television receiver, monitor device) which is an example of an electronic device according to an embodiment comprises, as illustrated in FIGS. 1 and 2, a casing 2, and a support 3 (supporting portion, table, stand). The support 3 is placed on a placement portion (placement surface P) such as a table, a desk, or a rack and supports the casing 2. The support 3 can turnably (movably, displaceably, and slidably) support the casing 2. The turning motion includes, e.g., swivel, pivot, and tilt.

In the present embodiment, the casing 2 has, as one example, a quadrangular shape (rectangular shape, as one example, in the present embodiment) in front view (hereinafter, referred to merely as “front view”, line of vision to FIG. 1) relative to a face 4a (display face, front face, first face) of a display unit 4, as illustrated in FIG. 1. Further, as illustrated in FIGS. 1 and 2, the casing 2 has a flat rectangular parallelepiped shape which is thin in a front-rear direction (thickness direction of the display unit 4). The casing 2 comprises a face 2a (front face) and a face 2b (rear surface) opposite the face 2a. The faces 2a and 2b are substantially parallel to each other. In front view (and in rear view), the casing 2 comprises four ends 2c to 2f (sides, edges) and four corners 2g to 2j (tip portion, bent portion, end portion). The ends 2c and 2e are each an example of a long side portion. The ends 2d and 2f are each an example of a short side portion.

Further, the casing 2 comprises, as one example, a wall 2k (front wall, first wall) and a wall 2m (rear wall, second wall). The wall 2k comprises the face 2a. The wall 2m comprises the face 2b. The wall 2k has a quadrangular frame-and-plate shape (rectangular frame-and-plate shape, as one example, in the present embodiment). The wall 2m has a quadrangular plate shape (rectangular plate shape, as one example, in the present embodiment). The casing 2 comprises, as one example, four walls 2n (side wall, end wall, vertical wall, connecting wall). The wall 2n comprises a face 2p (side surface, peripheral surface) connecting the wall 2k and wall 2m. The wall 2k comprises, as one example, a quadrangular opening 2r. The casing 2 can be made of, e.g., a metal material, a synthetic resin material, or the like (metal material, as one example, in the present embodiment).

The display unit 4 (display unit, display panel, display) is housed in the casing 2. For example, in the present embodiment, the face 4a of the display unit 4 that is positioned on the face 2a side is exposed to the front (outside) of the casing 2 through the opening 2r. A user can visually confirm, from the front side, the face 4a through the opening 2r. An image (video image) is displayed on the face 4a. In the present embodiment, the display unit 4 is formed into a quadrangular shape as one example (rectangular shape, as one example, in the present embodiment) in front view. Further, the display unit 4 has a flat rectangular parallelepiped shape which is thin in the front-rear direction.

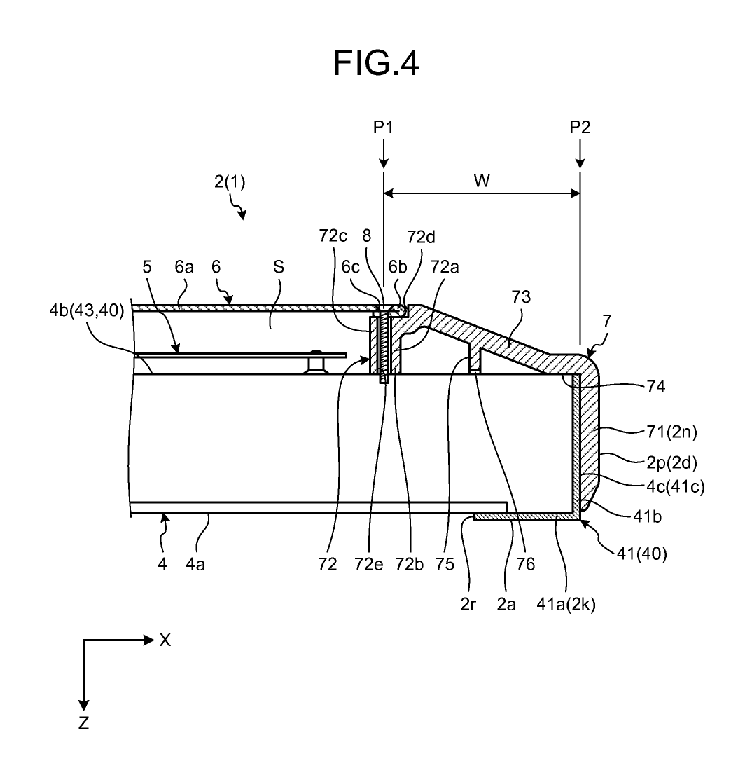

In the present embodiment, as one example, a circuit board 5 (board, control board, main board, printed circuit board) is positioned on a rear side (back side, wall 2m side, opposite side to the face 4a) of the display unit 4 in the casing 2, that is, in a gap S (space, chamber) formed between the display unit 4 and wall 2n, as illustrated in FIG. 4. The circuit board 5 is provided in substantially parallel to a face 4b (rear face, back face, second face) positioned opposite the face 4a of the display unit 4. Further, the circuit board 5 is provided spaced apart from the walls 2k, 2m, 2n, and the like, that is, with a space formed between itself and the walls 2k, 2m, 2n, and the like. Further, the circuit board 5 is fixed to the display unit 4 or the casing 2 by a fixing tool (not illustrated) such as a screw.

A plurality of components (electrical components, electronic components, elements, not illustrated) such as a central processing unit (CPU) are mounted on the circuit board 5, in addition to a connector. The plurality of components include a heating element. A cooling mechanism (heat receiver, heat conductor, heat radiator, fan, not illustrated) can be provided corresponding to a component (heating element) with a large heating value. The circuit board 5 and components mounted on the circuit board 5 constitute at least a part of a control circuit (not illustrated). The control circuit can include, for example, a video signal processing circuit, a tuner, a high-definition multimedia interface (HDMI) signal processor, an audio video (AV) input terminal, a remote control signal receiver, a controller, a selector, an on-screen display interface, a storage module, an audio signal processing circuit, and the like. The storage module includes a read only memory (ROM), a random access memory (RAM), a solid state drive (SSD), a hard disk drive (HDD), and the like. The control circuit controls output of a video image (moving picture or still image) on the face 4a of the display unit 4, audio output through a speaker (not illustrated), light emission through a light emitting diode (LED: not illustrated), and the like. The display unit 4, speaker, LED, and the like are each an example of an output module.

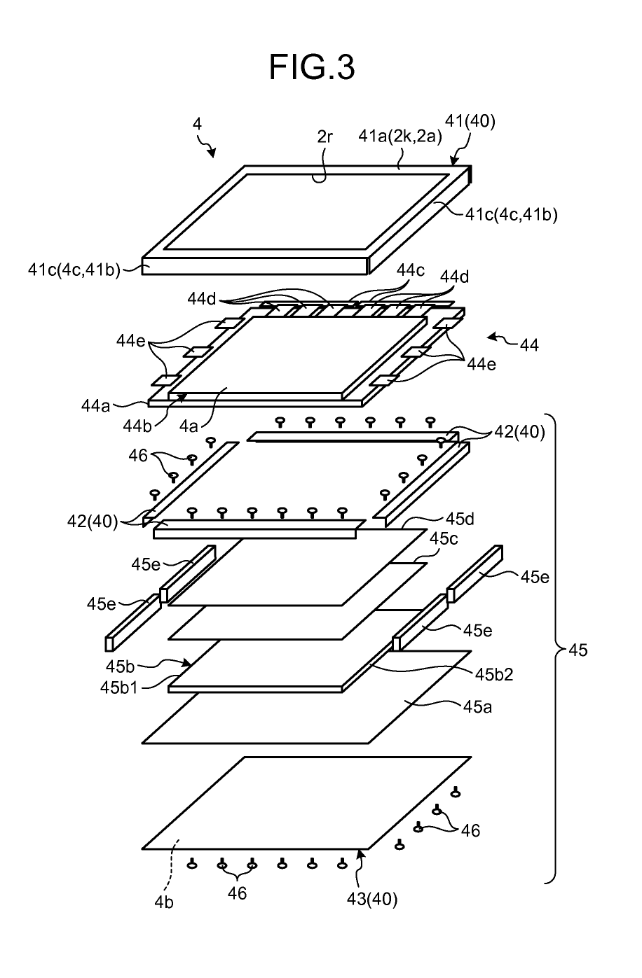

In the present embodiment, the display unit 4 comprises, as one example, a casing 40 as illustrated in FIG. 3. The casing 40 comprises a front bezel 41 (front mask, front side member, first member), a middle frame 42 (intermediate member), and a back plate 43 (bottom plate, rear side member, second member). A display module 44 (panel) and a backlight module 45 (backlight mechanism) are housed in the casing 40 of the display unit 4. The above constituent members are connected by a fixing tool 46 (e.g., a screw) to one another to be integrated.

The display module 44 (panel 44b, display panel) is, for example, a liquid crystal display (LCD), an organic electro-luminescent display (OELD), or the like. The display unit 4 may be provided with, at its front side, a thin plate-like or sheet-like transparent touch panel (input panel, input sheet, input device, not illustrated) or a cover that covers the face 4a. The touch panel can be provided on the panel 44b as so-called an in-cell touch panel. The display module 44 comprises, for example, a base 44a, a panel 44b, a source circuit board 44c, a source chip of film (COF) 44d, a gate COF 44e, and the like.

The backlight module 45 comprises, for example, a reflecting layer 45a, a light guide 45b, a prism layer 45c, a polarizing layer 45d, a light-emitting module 45e, and the like. The reflecting layer 45a, light guide 45b, prism layer 45c, and polarizing layer 45d have a flat quadrangular (rectangular) shape in front view and are laminated in the order illustrated in FIG. 3. The light-emitting module 45e comprising a plurality of light-emitting bodies (e.g., light emitting diodes (LEDs), not illustrated) is disposed along each of opposing ends 45b1 and 45b2 (left and right ends, in FIG. 3) of the light guide 45b so as to be opposed to and spaced apart from the same. The plurality of light-emitting bodies (not illustrated) provided in the light emitting module 45e are arranged in a line, for example, along each of the ends 45b1 and 45b2 so as to face the same. Light emitted from the light-emitting body enters the light guide 45b from the ends 45b1 and 45b2 of the plate-like light guide 45b. The light from the light guide 45b passes through (reflecting layer 45a), prism layer 45c, polarizing layer 45d to be irradiated on a rear face of the display module 44 as backlight. The configuration of the backlight module 45 is not limited to that described above. For example, the backlight module 45 may have configuration in which light enters the light guide 45b from a light emitting module (not illustrated) provided on a rear side (back side, wall 2m side, opposite side the face 4a) of the light guide 45b. Further, the configuration of the display unit 4 is not limited to that described above.

In the present embodiment, the casing 2 comprises, as one example, a member 6 (second member) and a member 7 (third member) in addition to the display unit 4, as illustrated in FIG. 4.

The member 6 has a size (smaller than that of the opening 2r) capable of being arranged inside the opening 2r provided in the wall 2k (41a) and is formed into a quadrangular plate-like shape. The member 6 covers the face 4b (second face) of the display unit 4 with the gap S interposed between the member 6 and face 4b. The member 6 and face 4b cross (cross at right angles, for example, in the present embodiment) a normal direction (thickness direction of casing 2, Z-direction) of the face 4a. That is, in the present embodiment, as one example, the member 6 and face 4b are substantially parallel to each other. A wall 6a (second wall) of the member 6 is exposed to a side (rear side, back side) opposite the face 4a and constitutes at least a portion of the wall 2m of the casing 2. The member 6 is a metal material (iron based material), as one example.

In the present embodiment, the front bezel 41 (first member) constituting the casing 40 of the display unit 4 comprises, as one example, a wall 41a covering a periphery of the face 4a and a wall 41b protruding rearward (to back side, to face 4b side) from a periphery of the wall 41a, as illustrated in FIG. 4. The front bezel 41 can be formed by press-molding (drawing) a metal member having a quadrangular frame-like shape. The wall 41a constitutes an inner edge (end) of the opening 2r. A face 41c of the wall 41b constitutes a face 4c (side face) of the display unit 4. The face 4c extends between the face 4a and face 4b, and crosses (crosses at right angles, for example, in the present embodiment) the face 4a and face 4b.

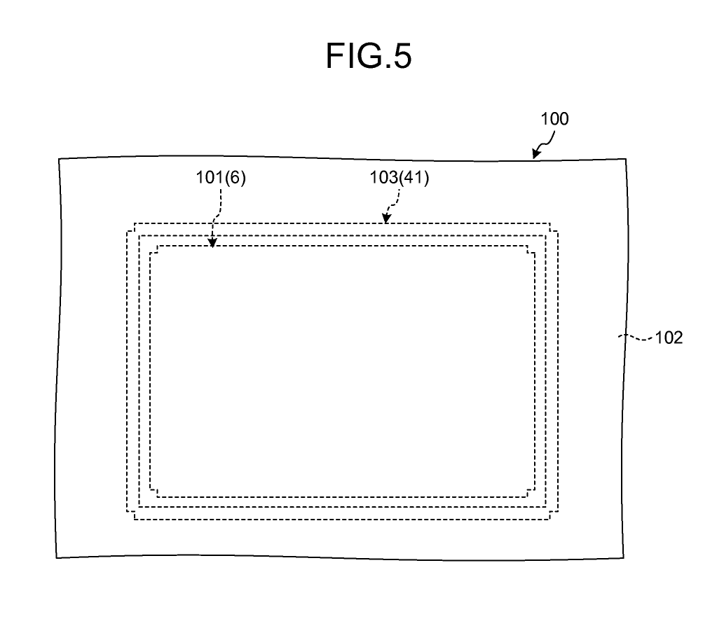

In the present embodiment, as one example, a quadrangular first part 101 cut out from a plate material 100 made of a metal material is used as the member 6 (second member), and a quadrangular frame shaped second part 103 cut out from an area 102 around the first part 101 is used as the front bezel 41 (first member), as illustrated in FIG. 5. The first part 101 is pressed to form the member 6, and the second part 103 is pressed to form the front bezel 41. Thus, in the present embodiment, as one example, the two members can be cut out from one plate material 100 in an efficient manner, thereby avoiding waste of material. A thickness of a general part (part not subjected to bending and compression in thickness direction) of the member 6 and a thickness of a general part of the front bezel 41 are substantially the same. Further, the front bezel 41 may be realized by four linear members or two L-shaped members.

As described above, the member 6 and front bezel 41 are cut out from one plate material, so that, as one example, the member 6 has a size capable of being arranged inside the opening 2r defined by the front bezel 41 in the present embodiment. Thus, in the present embodiment, as one example, a width W (distance) between a position P1 corresponding to an outer edge of the member 6 and a position P2 corresponding to the face 4c of the display unit 4 tends to be large. Further, the larger the thicknesses of the member 6 and front bezel 41, the larger the weight of the casing 2 becomes. Thus, in the present embodiment, as one example, the member 7 is used to efficiently enhance rigidity of the casing 2.

The member 7 (third member) can be formed by extrusion molding of an aluminum alloy, as one example. In this case, the member 7 is provided for each of the ends 2c to 2f (see FIG. 1) of the casing 2. The use of the extrusion molding advantageously eliminates the need to perform outer surface polishing treatment. Further, thicknesses of walls (wall 71, support 72, wall 73, etc.) of the member 7 are larger (thicker) than those (thickness of plate material 100) of walls (walls 41a, 41b, and 6a) of the front bezel 41 and member 6. Thus, as one example, rigidity of the casing 2 is easily increased by the use of the member 7.

Further, as illustrated in FIG. 4, the member 7 comprises a wall 71 (third wall), a support 72 (wall), and a wall 73 (fourth wall). The wall 71 covers the face 4c (third face) of the display unit 4. The wall 71 constitutes at least a portion of the wall 2n (side wall) and face 2p (side face) of the casing 2.

The support 72 (wall, protrusion) comprises a wall 72a. The wall 72a extends along both the thickness direction (Z-direction, up-down direction in FIG. 4) of the casing 2 and a direction (Y-direction, direction perpendicular to the paper surface in FIG. 4) along the end 2d of the casing 2. An end 72b (leading end, tip end) of the wall 72a is made in contact with the face 4b of the display unit 4. A concave portion 72d is formed at an end 72c (support) positioned opposite the end 72b of the wall 72a. An end 6b of the member 6 is housed in the concave portion 72d. The end 6b of the member 6 is bent to the face 4a side at a fixed width. As a result, a cut surface of the member 6 from the plate material 100 is separated away from the outer edge of the member 6. The support 72 supports the end 6b of the member 6 at a position (end 72c) separated away, toward a side opposite (rear side, back side) the face 4a (first face), from the face 4b (second face) of the display unit. Further, a plurality of openings 72e are formed in the wall 72a so as to be arranged in a direction (Y-direction, direction perpendicular to the paper surface in FIG. 4) along the end 2d at intervals. The openings 72e each extend in the thickness direction (Z-direction, up-down direction in FIG. 4) of the casing 2. A fixing tool 8 (e.g., a screw, in the present embodiment) penetrates the opening 72e and an opening 6c (through hole or cut) of the member 6 overlapped with the opening 72e to be fixed to the display unit 4. That is, the display unit 4, the member 6, and the member 7 are integrated with (fixed to) one another by the fixing tool 8.

In the present embodiment, the wall 73 connects the wall 71 and support 72, as one example. Further, the wall 73 is formed so as to approach a center C side (see FIGS. 1 and 2, left side in FIG. 4) of the display unit 4 as it advances from the wall 71 to the support 72 (upward, in FIG. 4). Thus, according to the present embodiment, as compared to, e.g., a configuration in which the wall 73 extends along the face 4b, deformation of the wall 73 due to a load input from the fixing tool 8 and display unit 4 upon fixing of the fixing tool 8 is easily suppressed. Further, as one example, existence of an inclined area in the outer face of the casing 2 makes the casing 2 look thin in appearance.

In the present embodiment, the member 7 comprises, as one example, a contact portion 74 contacting the face 4b at a position separated away from the support 72 toward the wall 71 side (right side in FIG. 4). In the present embodiment, as one example, the contact portion 74 is provided at an end (position close to the wall 71) of the wall 73 on the wall 71 side. Thus, according to the present embodiment, as one example, the two locations (end 72b of the support 72 and contact portion 74) contact the face 4b of the display unit 4 in each member 7, so that by disposing the two locations (end 72b and contact portion 74) on the same plane, deviation of a position and a posture between the (the face 4b of) display unit 4 and member 7 is unlikely to occur. Thus, as one example, a disadvantageous phenomenon in which a gap between the wall 71 and side face 4c of the display unit 4 is widen at a leading end side (face 4a side) of the wall 71.

In the present embodiment, the wall 73 comprises, as one example, a protrusion 75 protruding toward the display unit 4 side from a position between the support 72 and wall 71. Existence of the protrusion 75 enhances rigidity and strength of the member 7. A cushioning material 76 (e.g., elastomer or sponge) is interposed between the protrusion 75 and face 4b.

In the present embodiment, as one example, all the four third members 7 provided along the respective ends 2c to 2d of the casing 2 have the same shape as the sectional shape illustrated in FIG. 4.

As described above, in the present embodiment, the casing 2 comprises, as one example, the front bezel 41 (first member) having the wall 41a (first wall) defining the quadrangular opening 2r and quadrangular plate-like member 6 (second member) having a size capable of being arranged inside the opening 2r and exposed on a side opposite to the face 4a. Thus, according to the present embodiment, as one example, the front bezel 41 and member 6 can be efficiently cut out from the plate material 100.

Further, in the present embodiment, the member 7 (third member) comprises, as one example, the wall 71 (third wall) and wall 73 (fourth wall). The wall 71 covers the face 4c (third face) of the display unit 4 and has a thickness larger than those of the wall 41a (first wall) and wall 6a (second wall). Further, the wall 73 connects the wall 71 (third wall) and support 72 and has a thickness larger than those of the wall 41a and wall 6a. Thus, according to the present embodiment, as one example, rigidity of the casing 2 is enhanced by the comparatively highly rigid member 7 connecting the display unit 4 and member 6.

### Modification

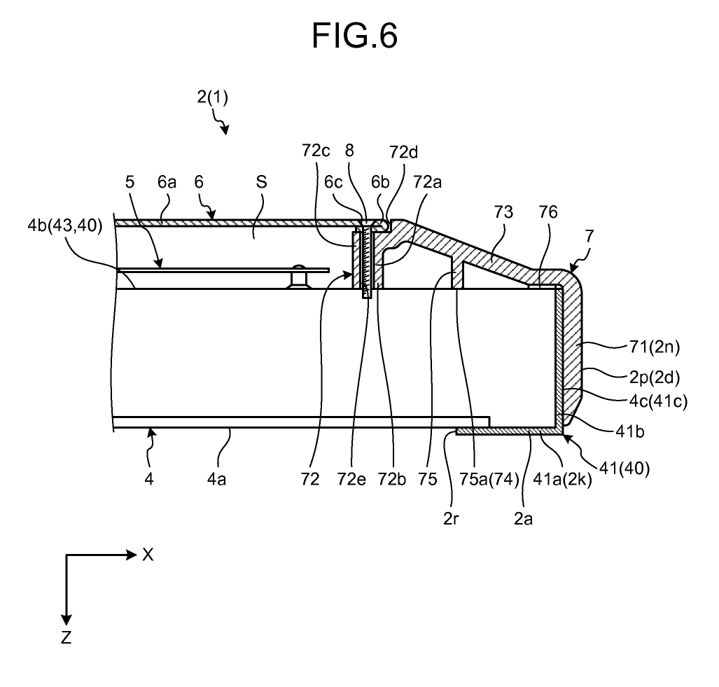

In a modification illustrated in FIG. 6, as an example, an end 75a (leading end, tip end) of the protrusion 75 contacts the face 4b. That is, the end 75a serves as an example of the contact portion 74. The wall 73 does not directly contact the face 4b at its wall 71 side, and the cushioning material 76 is interposed between the wall 73 and face 4b. Also in this modification, it is possible to obtain the same results (effects) as those obtained based on the configuration of the above embodiment.

While the embodiment and modification have been described, these embodiment and modification have been presented by way of example only, and are not intended to limit the scope of the invention. Indeed, the embodiment and modification described herein may be embodied in a variety of other forms; furthermore, various omissions, substitutions, combinations and changes in the form of the embodiments described herein may be made without departing from the spirit of the invention. These embodiment and modification are included in the scope and spirit of the invention and are included in the invention described in the claims and its equivalents. Further, the components may be partially substituted between the embodiment and modification. The specifications of each component (structure, type, direction, shape, size, length, width, thickness, height, number, arrangement, position, materials, etc.) may be appropriately changed to be embodied. The display device according to the embodiment and modification comprises four third members provided along the respective end portions of the casing; however, the display device may comprise two third members each having an L-shape or one third member having a quadrangular frame shape. Further, the third member may be formed by a method other than the extrusion molding, such as die casting.

What is claimed is:

1. A display device comprising:
a display unit comprising a display panel and a first member, the display panel comprising a first face on which an image is displayed, the first member comprising a first wall covering a periphery of the first face and defining an opening configured to expose the first face;
a second member configured to cover a second face of the display unit opposite the first face, a gap being provided between the second wall and the second face; and
a third member comprising a third wall, a support, and a fourth wall, wherein
the third wall is configured to cross the first face and the second face, is configured to cover a third face of the display unit extended between the first face and the second face, and has a thickness thicker than thicknesses of the first wall and the second wall,
the support is configured to support the second member at a position separated from the second face of the display unit toward a side opposite the first face, and
the fourth wall is extended between the third wall and the support.

2. The display device of claim 1, wherein the second member is configured to have a size capable of being arranged inside the opening.

3. The display device of claim 1, wherein the fourth wall is formed so as to approach a center of the display unit as the fourth wall advances from the third wall to the support.

4. The display device of claim 1, wherein
the second and third members are fixed to the display unit by a fixing tool configured to penetrate through a periphery of the second wall and the support, and
the third member comprises a contact portion configured to be in contact with the second face at a position separated from the support toward the third wall.

5. The display device of claim 1, wherein the fourth wall comprises a protrusion configured to protrude toward the display unit from a position between the support and third wall.

6. A display device comprising:
a display unit comprising a display panel and a first member, the display panel comprising a first face on which an image is displayed, the first member comprising a first wall covering a periphery of the first face and defining an opening configured to expose the first face;
a second member configured to cover a second face of the display unit opposite the first face, a gap being provided between the second wall and the second face; and
a third member comprising a third wall, a support, and a fourth wall, wherein
the third wall is configured to cross the first face and the second face, and is configured to cover a third face of the display unit extended between the first face and the second face,
the support is configured to support the second member at a position separated from the second face of the display unit toward a side opposite the first face, and
the fourth wall is extended between the third wall and the support, and has a thickness thicker than thicknesses of the first wall and the second wall.

7. The display device of claim 6, wherein the second member is configured to have a size capable of being arranged inside the opening.

8. The display device of claim 6, wherein the fourth wall is formed so as to approach a center of the display unit as the fourth wall advances from the third wall to the support.

9. The display device of claim 6, wherein
the second and third members are fixed to the display unit by a fixing tool configured to penetrate through a periphery of the second wall and the support, and
the third member comprises a contact portion configured to be in contact with the second face at a position separated from the support toward the third wall.

10. The display device of claim 6, wherein the fourth wall comprises a protrusion configured to protrude toward the display unit from a position between the support and third wall.
